(19) United States
(12) Patent Application Publication
(10) Pub. No.: US 2025/0298061 A1
(43) Pub. Date: Sep. 25, 2025

(54) CIRCUIT AND METHOD FOR BATTERY DETECTION

(71) Applicant: Nuvoton Technology Corporation, Hsinchu Science Park (TW)

(72) Inventors: Jing Luen HUANG, Hsinchu Science Park (TW); Shih-Hsun TUNG, Hsinchu Science Park (TW); Wei Cheng LIN, Hsinchu Science Park (TW); Ming-Che HUNG, Hsinchu Science Park (TW)

(21) Appl. No.: 18/964,780

(22) Filed: Dec. 2, 2024

(30) Foreign Application Priority Data
Mar. 21, 2024 (TW) 113110529

(51) Int. Cl. G01R 19/165; G01R 31/364

(52) U.S. Cl. CPC G01R 19/16542; G01R 19/16528; G01R 19/16557; G01R 31/364

(57) ABSTRACT

A circuit for battery detection including a power-on reset (POR) block, an analog-to-digital converter (ADC) circuit, a switch circuit, and a logic control circuit is provided. The POR block is coupled to a node and is configured to output an output voltage with logic high level or logic low level when the node has a battery voltage higher or lower than a preset value, respectively. The switch circuit is coupled to the logic control circuit and the ADC circuit. The logic control circuit is coupled to the POR block and is configured to generate a control signal with the logic low level when the output voltage is at the logic low level, so that the switch circuit disconnects the ADC circuit and the node, and the ADC circuit does not read the battery voltage.

### CROSS REFERENCE TO RELATED APPLICATIONS

This application claims priority of Taiwan Patent Application No. 113110529, filed on Mar. 21, 2024, the entirety of which is incorporated by reference herein.

### BACKGROUND OF THE INVENTION

### Field of the Invention

The present invention relates to a battery detection circuit, and in particular, to a battery detection circuit that uses an internal circuit of an integrated circuit to detect the presence of a battery.

### Description of the Related Art

Motherboards are widely used in various computer systems, making it possible for the same motherboard to be used in various systems. For example, the same motherboard may be used in both automated teller machine (ATM) systems and personal computer (PC) systems. An ATM system is powered directly by the system voltage, while a PC system needs to be connected to a battery (e.g., a mercury battery).

However, when a motherboard that needs to be connected to a battery is being used in an application that requires a motherboard that is not connected to a battery, the voltage reading circuit inside the motherboard will not be able to read the normal battery voltage, resulting in unpredictable read results. When these unpredictable read results are reported to the upper-layer software (e.g., the basic input output system (BIOS)), the upper-layer software will determine that the battery is abnormal due to these incorrect read values. In addition, manufacturing different motherboards for different systems will increase costs. Therefore, a solution is needed to solve the aforementioned problems.

### BRIEF SUMMARY OF THE INVENTION

In some embodiments, the present disclosure provides a battery detection circuit including a power-on-reset (POR) block, an analog-to-digital converter (ADC) circuit, a switch circuit, and a logic control circuit. The POR block is coupled to a node for outputting an output voltage with logic high level when the node has a battery voltage higher than a preset value. The POR circuit is further configured to output the output voltage with logic low level when the node does not have a battery voltage higher than the preset value. The switch circuit is coupled to the logic control circuit and the ADC circuit. The logic control circuit is coupled to the POR block, and in response to the output voltage having logic low level, a control signal with logic low level is generated, so that the switch circuit is opened and the ADC circuit and the node are disconnected, and the ADC circuit will not read the battery voltage.

In some embodiments, the present disclosure further provides a method for battery detection, including receiving a battery voltage from a node through a power-on reset (POR) block and outputting an output voltage with logic high level when the battery voltage is higher than a preset value. The method further includes detecting the output voltage and generating a determination signal and a control signal by a logic control circuit. The method further includes receiving the control signal at a switch circuit, wherein when the output voltage is at logic high level, the determination signal has a first logic level. Additionally, the control signal turns on the switch circuit and receives and reads the battery voltage through an analog-to-digital converter circuit. When the output voltage is at a logic low level, the determination signal has a second logic level, and the control signal turns off the switch circuit so that the analog-to-digital converter circuit cannot receive the battery voltage.

### BRIEF DESCRIPTION OF THE DRAWINGS

FIG. 1 shows an example of a battery detection circuit according to the embodiments of the present invention; and

FIG. 2 shows a flow chart of an example of a method for battery detection according to the embodiments of the present invention.

### DETAILED DESCRIPTION OF THE INVENTION

To make the aforementioned and other objects, features, and advantages of the present invention more clearly understandable, preferred embodiments are listed below and are described in detail below regarding the accompanying drawings:

Some embodiments are summarized below so that those with ordinary skills in the art can more easily understand the embodiments of the present invention. However, these embodiments are only examples and are not used to limit the embodiments of the present invention. It will be understood that those with ordinary skills in the art can adjust the embodiments described below according to needs, such as changing the process sequence and/or including more or fewer steps than described here, and these adjustments are not It does not exceed the scope of the embodiments of the present invention.

In addition, other elements may be added based on the embodiments described below. For example, the description of “forming a second element on a first element” may include an embodiment in which the first element is in direct contact with the second element, or may include other elements between the first element and the second element such that the first element is not in direct contact with the second element. Additionally, the upper-lower relationship between the first element and the second element may change as the device is operated or used in different orientations. In addition, repeated reference numbers and/or letters may be used in different embodiments. This repetition is for simplicity and clarity and is not used to indicate the relationship between the different embodiments.

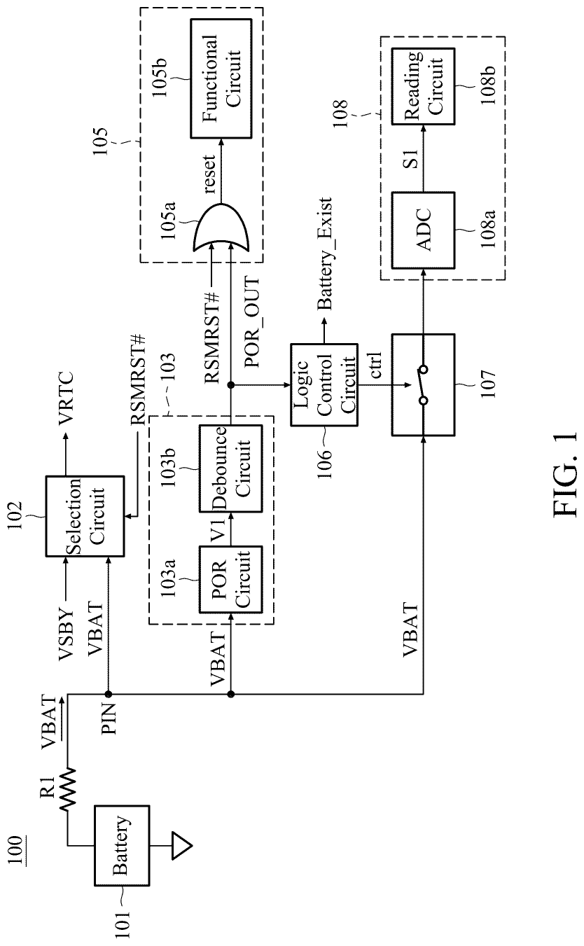

FIG. 1 shows an example of a battery detection circuit 100 according to an embodiment of the present disclosure. In some embodiments, the battery detection circuit 100 may be located on a chip, and in some embodiments, the battery detection circuit 100 may be a chip, wherein the chip may be a part of an electronic system (e.g., a motherboard, etc.). The battery detection circuit 100 may include a power-on reset (POR) block 103, a logic control circuit 106, a switching circuit 107, and an analog-to-digital converter (ADC) circuit 108. As shown in FIG. 1, a battery 101 is coupled to a node PIN through a resistor R1 to output a battery voltage VBAT. The POR block 103 is coupled to the node PIN to receive the battery voltage VBAT. When the battery voltage VBAT is higher than a preset value, the POR block 103 outputs an output voltage POR_OUT with logic high level to the logic control circuit 106. On the contrary, when the battery voltage VBAT is not higher than the preset value, the POR block 103 outputs the output voltage POR_OUT with logic low level to the logic control circuit 106. In addition, the switch circuit 107 may be a circuit that switches channels in a polling fashion (e.g., an analog multiplexer (AMUX)). That is, the switch circuit 107 has a plurality of channels for inputting a plurality of voltages to the ADC circuit 108, and the battery voltage VBAT is one of the aforementioned voltages.

In some embodiments, the POR block 103 may further include a POR circuit 103a and a debounce circuit 103b. The POR circuit 103a is configured to receive the battery voltage VBAT from the node PIN and generate a first voltage V1. In addition, when a selection signal RSMRST # has logic low level, the POR circuit 103a can reset a functional circuit 105b each time the POR circuit 103a receives a voltage (e.g., the battery voltage VBAT), to restore the functional circuit 105b to an initial state for the following operations. Then, the debounce circuit 103b receives the first voltage V1 and debounces the first voltage V1 to generate and output the output voltage POR_OUT to the logic control circuit 106. Specifically, the debounce circuit 103b outputs the output voltage POR_OUT with logic high level to the logic control circuit 106 when the first voltage V1 is higher than a first threshold (i.e., when the battery voltage VBAT exists). On the contrary, the debounce circuit 103b outputs the output voltage POR_OUT with logic low level to the logic control circuit 106 when the first voltage V1 is lower than the first threshold (i.e., when the battery voltage VBAT does not exist).

The logic control circuit 106 detects the output voltage POR_OUT and generates a determination signal Battery_Exist and a control signal ctrl. The determination signal Battery_Exist can be stored in a register (not shown) to provide subsequent operation utilization. The control signal ctrl is used to control the switch circuit 107. When the logic control circuit 106 detects the output voltage POR_OUT with logic high level (i.e., the battery voltage VBAT exists and is higher than the first threshold), the control signal ctrl turns on the switch circuit 107 to connect the node PIN and the ADC circuit 108. Additionally, the logic control circuit 106 stores the determination signal Battery_Exist with a first logic level (e.g., logic “1”) into the register (i.e., determines that the battery 101 exists). On the contrary, when the logic control circuit 106 detects the output voltage POR_OUT with logic low level (i.e., the battery voltage VBAT does not exist or is lower than the first threshold), the control signal ctrl turns off the switch circuit 107 to disconnect the node PIN and the ADC circuit 108. Additionally, the logic control circuit 106 stores the determination signal Battery_Exist with a second logic level (e.g., logic “0”) into the register (i.e., determines that the battery 101 does not exist or is abnormal).

In some embodiments, the ADC circuit 108 may further include an ADC 108a and a reading circuit 108b. The ADC 108a is coupled between the switch circuit 107 and the reading circuit 108b. When the switch circuit 107 turns on, the ADC 108a receives the battery voltage VBAT and converts the battery voltage VBAT into a digital signal S1 and output to the reading circuit 108b. The reading circuit 108b can determine whether to read the digital signal S1 output by the ADC 108a according to the logic level of the determination signal Battery_Exist. Specifically, when detecting the output signal POR_OUT is at logic high level, the logic control circuit 106 stores the determination signal Battery_Exist with the first logic level (e.g., logic “1”) into the register. Additionally, the switch circuit 107 is turned on, so that the ADC 108a receives the battery voltage VBAT with the first logic level and output the digital signal S1 to the reading circuit 108b. Then, the reading circuit 108b reads the determination signal Battery_Exist with the first logic level (e.g., logic “1”) from the register, so that the reading circuit 108b reads the digital signal S1. On the contrary, when detecting that the output signal POR_OUT has logic low level, the logic control circuit 106 stores the determination signal Battery_Exist with the second logic level (e.g., logic “0”) into the register. Additionally, the switch circuit 107 is turned off, so that the ADC 108a stops receiving battery voltage VBAT. Then, the reading circuit 108b reads the determination signal Battery_Exist with the second logic level (e.g., logic “0”) from the register, so that the reading circuit 108b does not perform read operation (e.g., the reading circuit 108b can set the switch circuit 107 skips the channel of the battery voltage VBAT).

In addition, the battery detection circuit 100 may further include a selection circuit 102 and a functional block 105. As shown in FIG. 1, the battery 101 can also output the battery voltage VBAT to the selection circuit 102, and the selection circuit 102 can select the battery voltage VBAT as an operating voltage VRTC to drive the functional block 105 to perform specific functions related to the battery voltage VBAT. For example, the specific functions may be functions of personal computers that require battery voltage VBAT for operation). However, when a system voltage VSBY is input to the selection circuit 102, the selection circuit 102 selects the system voltage VSBY as the operating voltage VRTC.

In addition, as shown in FIG. 1, the functional block 105 can also receive the output voltage POR_OUT and the selection signal RSMRST # from the POR block 103. The selection circuit 102 uses the selection signal RSMRST # to select the system voltage VSBY or the battery voltage VBAT as the operating voltage VRTC. Specifically, the selection signal RSMRST # can be from other circuits, such as other circuits in the electronic system including the battery detection circuit 100, such as input/output (I/O) control chips or embedded control chips. Additionally, when the selection signal RSMRST # is at logic high level, it indicates that the system voltage VSBY is ready, and the selection circuit 102 will select the system voltage VSBY as the operating voltage VRTC.

In some embodiments, the functional block 105 may further include an OR gate 105a and a functional circuit 105b. The OR gate 105a is used to receive the output voltage POR_OUT and the selection signal RSMRST # and generate a reset signal reset. When the reset signal reset is at logic low level, the functional circuit 105b will be reset (i.e., will not operate). That is, in response to only the output voltage POR_OUT is input to the functional block 105, when the battery voltage VBAT does not exist, or the battery voltage VBAT is not higher than the first threshold, the reset signal reset will remain at logic low level so that functional circuit 105b cannot operate. Therefore, the selection signal RSMRST # ensures that the functional circuit 105b can continue to perform specific functions related to the battery voltage VBAT (e.g., functions of a personal computer that require battery voltage VBAT for operation) when the battery voltage VBAT does not exist or is abnormal (i.e., not higher than the first threshold).

In addition, different components and/or blocks of the battery detection circuit 100 can be driven by different voltages. For example, the POR block 103 (or the POR circuit 103a and/or the debounce circuit 103b) can be driven by the battery voltage VBAT. The functional block 105 (or the functional circuit 105b) can be driven by the operating voltage VRTC. The ADC circuit 108 (or the ADC 108a and/or the reading circuit 108b) can be driven by other voltages, such as other voltages generated by the system voltage VSBY.

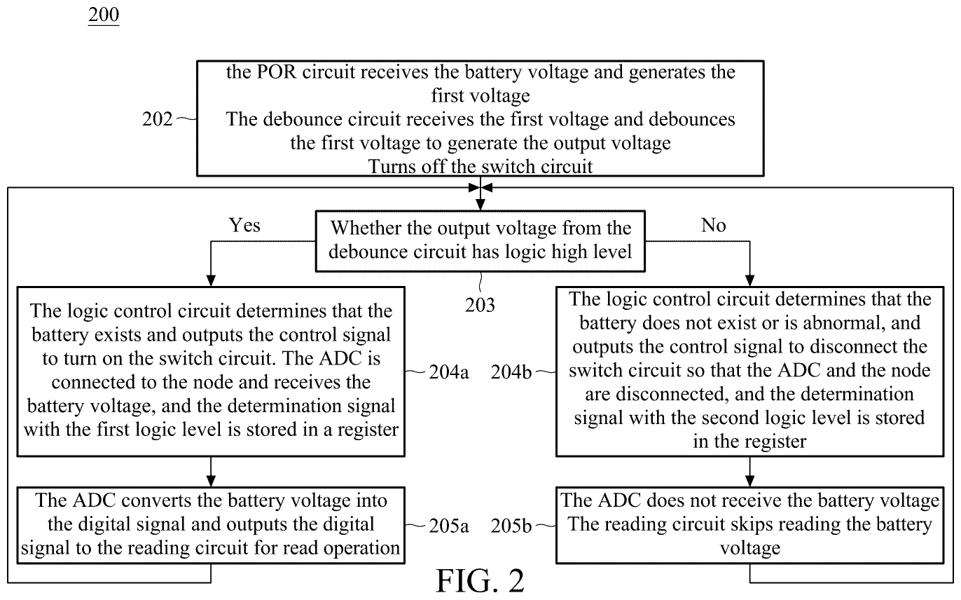

FIG. 2 shows a flow chart of an example of a method 200 according to an embodiment of the present disclosure. The method 200 can be implemented using the battery detection circuit 100. The method 200 begins with operation 202.

In operation 202, the method 200 performs an initialization setting on the battery detection circuit 100. The initialization setting includes: when the operating voltage VRTC is not zero, the POR circuit 103a receives the battery voltage VBAT and generates the first voltage V1. The debounce circuit 103b receives the first voltage V1 and debounces the first voltage V1 to generate the output voltage POR_OUT. At the same time, the switch circuit 107 is turned off, and the determination signal Battery_Exist is set to a second logic level (e.g., logic “0”).

Next, in operation 203, the logic control circuit 106 detects the logic level of the output voltage POR_OUT output by the POR block 103 (or the debounce circuit 103b). In response to the output voltage POR_OUT having logic high level, the method 200 proceeds to operation 204a. In operation 204a, the logic control circuit 106 determines that the battery 101 exists and outputs the control signal ctrl to turn on the switch circuit 107. As a result, the ADC 108a is connected to the node PIN and receives the battery voltage VBAT, and, at the same time, the determination signal Battery_Exist with the first logic level (e.g., logic “1”) is stored in a register. Next, the method 200 proceeds to operation 205a.

In operation 205a, the ADC 108a converts the battery voltage VBAT into the digital signal S1 and outputs the digital signal S1 to the reading circuit 108b for read operation. Then, the method 200 returns to operation 203 for the next detection of whether the output voltage POR_OUT has logic high level (i.e., detecting whether the battery voltage VBAT exists and is higher than the first threshold).

In operation 203, in response to the logic control circuit 106 detecting that the output voltage POR_OUT output by the POR block 103 (or the debounce circuit 103b) has logic low level (i.e., the battery voltage VBAT does not exist or is lower than the first threshold), the method 200 proceeds to operation 204b. In operation 204b, the logic control circuit 106 determines that the battery 101 does not exist or the battery voltage VBAT is abnormal. Then, the logic control circuit 106 outputs the control signal ctrl to disconnect the switch circuit 107, so that the ADC 108a and the node PIN are disconnected and the ADC 108a cannot receive the battery voltage VBAT. At the same time, the determination signal Battery_Exist with the second logic level (e.g., logic “0”) is stored in the register. Next, the method 200 proceeds to operation 205b.

In operation 205b, since the switch circuit 107 disconnects the connection between the ADC 108a and the node PIN, the ADC 108a does not receive the battery voltage VBAT. The reading circuit 108b skips reading the battery voltage VBAT after reading the determination signal Battery_Exist with the second logic level. Then, the method 200 returns to operation 203 for the next detection of whether the output voltage POR_OUT has logic high level (i.e., detecting whether the battery voltage VBAT exists and is higher than the first threshold).

As mentioned above, the battery detection circuit proposed herein uses the POR circuit to receive the battery voltage, and outputs the corresponding output voltage to the logic control circuit for detection, so that the battery detection circuit proposed herein can continuously receive and detect the battery voltage. Such a configuration of continuously receiving and detecting the battery voltage can increase the sensitivity of determining whether the battery is present. Additionally, it can also immediately control the switch circuit to disconnect the node and the ACD when detecting the absence of the battery or abnormal battery voltage, and enabling the reading circuit to not read the battery voltage to save power.

What is claimed is:

1. A battery detection circuit, comprising:
a power-on-reset (POR) block, configured to be coupled to a node for outputting an output voltage with a logic high level when the node has a battery voltage higher than a preset value, and when the node does not have the battery voltage higher than the preset value, the output voltage with a logic low level is output;
an analog-to-digital converter (ADC) circuit;
a switch circuit, coupled to the ADC circuit; and
a logic control circuit, coupled to the POR block, and configured to generate a control signal having the logic low level in response to the output voltage having the logic low level, causing the switch circuit to disconnect the connection between the ADC circuit and the node, wherein the ADC circuit does not read the battery voltage.

2. The battery detection circuit as claimed in claim 1, wherein the logic control circuit generates the control signal with the logic high level in response to the output voltage having the logic high level, causing the switch circuit to close the connection between the ADC circuit and the node, wherein the ADC circuit reads the battery voltage.

3. The battery detection circuit as claimed in claim 1, wherein in response to the output voltage having the logic high level, the logic control circuit generates the control signal with the logic high level, and stores a determination signal with a first logic level into a register; and
in response to the output voltage having the logic low level, the logic control circuit generates the control signal with the logic low level and stores the determination signal with a second logic level into the register.

4. The battery detection circuit as claimed in claim 3, wherein the ADC circuit comprises:
an analog-to-digital converter (ADC), coupled to the switch circuit and used to receive the battery voltage and generate a digital signal when the switch circuit is turned on; and
a reading circuit, coupled to the ADC for reading the digital signal when the determination signal has the first logic level, and when the determination signal has the second logic level, the reading circuit does not read the digital signal.

5. The battery detection circuit as claimed in claim 1, wherein the POR block comprises:
a power-on reset (POR) circuit, coupled to the node and configured to receive the battery voltage and generate a first voltage; and
a debounce circuit, coupled between the POR circuit and the logic control circuit, and configured to debounce the first voltage to generate and output the output voltage to the logic control circuit.

6. The battery detection circuit as claimed in claim 1, further comprising:
a selection circuit, configured to receive a system voltage, the battery voltage, and a selection signal, wherein when the selection signal has the logic high level, the selection circuit selects the system voltage as an operating voltage.

7. The battery detection circuit as claimed in claim 6, further comprising:
a functional block, configured to receive the output voltage and the selection signal to perform specific functions related to the battery voltage.

8. The battery detection circuit as claimed in claim 7, wherein the functional block includes an OR gate and a functional circuit, and the OR gate is configured to receive the selection signal and the output voltage and output a reset signal to determine whether the functional circuit performs the specific function related to the battery voltage.

9. The battery detection circuit as claimed in claim 1, wherein the battery detection circuit is on a chip.

10. A method for battery detection, comprising:
receiving a battery voltage from a node through a power-on-reset (POR) block, and outputting an output voltage with a logic high level when the battery voltage is higher than a preset value;
detecting the output voltage and generating a determination signal and a control signal through a logic control circuit; and
receiving the control signal at a switch circuit,
wherein when the output voltage has the logic high level, the determination signal has a first logic level, and the control signal turns on the switch circuit, and receives and reads the battery voltage through an analog-to-digital converter (ADC) circuit; and
wherein when the output voltage has a logic low level, the determination signal has a second logic level, and the control signal turns off the switch circuit so that the ADC circuit does not receive the battery voltage.
